(19) United States
(12) Patent Application Publication
(10) Pub. No.: US 2015/0166881 A1
(43) Pub. Date: Jun. 18, 2015

(54) PACKAGING MATERIAL AND LED PACKAGING STRUCTURE CONTAINING THE SAME

(71) Applicant: Lextar Electronics Corporation, Hsinchu (TW)

(72) Inventors: Min-Ya CHAN, Xinpu Township (TW); Chen-Chi MA, Hsinchu City (TW); Sheng-Tsung HSIAO, Taoyuan City (TW); Wei-Hao LIAO, Taichung City (TW)

(21) Appl. No.: 14/336,459

(22) Filed: Jul. 21, 2014

(30) Foreign Application Priority Data
Dec. 12, 2013 (TW) 102145887

(51) Int. Cl. C09K 11/02; H01L 33/58; H01L 33/50; H01L 33/56

(52) U.S. Cl. CPC C09K 11/025; H01L 33/56; H01L 33/58; H01L 33/507

(57) ABSTRACT

A packaging material is provided including a transparent insulating material, a wavelength-converting material and a hydrophobic light-scattering material. The wavelength-converting material and the hydrophobic light-scattering material are mixed in the transparent insulating material. An LED packaging structure containing the packaging material is also provided herein.

### RELATED APPLICATIONS

This application claims priority to Taiwan Application Serial Number 102145887 filed Dec. 12, 2013, which is herein incorporated by reference.

### BACKGROUND

1. Technical Field

The present disclosure relates to a packaging material and an LED packaging structure containing thereof, and more particularly, to a packaging material having a hydrophobic light-scattering material and an LED packaging structure containing thereof.

2. Description of Related Art

A packaging material of a conventional light-emitting diode (LED) usually includes a fluorescent powder used as a wavelength-conversion material. A short-wavelength LED, such as a blue-ray LED, is commonly used as an exciting light source to convert wavelengths from the fluorescent powder dispersed in the packaging material, so as to generate LEDs emitting lights with different colors. For example, to generate the LEDs emitting various color lights, a blue light emitted by the blue-ray LED first irradiates the fluorescent powder, and the fluorescent powder may absorb the exciting energy of the blue light and convert the energy into other color light with a longer wavelength such as red light, yellow light or green light.

The packaging material of the conventional LED generally has poor resistance to water and sulfur vapor, which results in the oxidization or corrosion of a conductive layer of the LED, or deterioration of the fluorescent powder of the packaging material reducing the reliability of the LED packaging structure. Therefore, there is a need for an improved packaging material and a packaging structure containing thereof, so as to solve the aforementioned problems met in the art.

### SUMMARY

The present disclosure provides a packaging material and a packaging structure containing thereof, so as to solve the aforementioned problems met in the art. By increasing the hydrophobicity of a packaging material, the reliability of a LED packaging structure is enhanced.

One embodiment of the present disclosure is to provide a packaging material. The packaging material includes a transparent insulating material, a wavelength-conversion material and a hydrophobic light-scattering material. The wavelength-conversion material and the hydrophobic light-scattering material are dispersed in the transparent insulating material.

According to one embodiment of the present disclosure, the transparent insulating material includes a transparent silicone or a transparent plastic.

According to one embodiment of the present disclosure, the wavelength-conversion material and the hydrophobic light-scattering material are in graininess.

According to one embodiment of the present disclosure, the content of the wavelength-conversion material in the packaging material is in a range of 0.1-1 wt %.

According to one embodiment of the present disclosure, the wavelength-conversion material includes a fluorescent powder, a dye, a pigment or a combination thereof.

According to one embodiment of the present disclosure, the hydrophobic light-scattering material includes a core material and a hydrophobic structure positioned on a surface of the core material.

According to one embodiment of the present disclosure, the core material includes a metal compound, a nonmetal compound or a metal compound and a nonmetal compound.

According to one embodiment of the present disclosure, the metal compound includes titanium oxide, aluminum oxide, aluminum nitride, zinc oxide or zirconium oxide.

According to one embodiment of the present disclosure, the nonmetal compound includes silicon oxide, boron nitride or a clay.

According to one embodiment of the present disclosure, the hydrophobic structure is composed of a plurality of hydrophobic side chains.

According to one embodiment of the present disclosure, the hydrophobic side chains includes trimethoxy(octadecyl) silane, 1H,1H,2H,2H-perfluorotriethoxysilane or trichloro(1H,1H,2H,2H-perfluorooctyl) silane.

According to one embodiment of the present disclosure, the molar ratio of the hydrophobic side chains and the core material is 3:1.

Another embodiment of the present disclosure is to provide a LED packaging structure. The LED packaging structure includes at least one LED chip and the packaging material mentioned above. The packaging material covers the LED chip.

Further another embodiment of the present disclosure is to provide a method for manufacturing a packaging material. The method includes the steps of: providing a core material; performing a hydration of the core material to form a plurality of hydroxyl groups (—OH) on a surface of the core material; oxidizing a part of the hydroxyl groups to form a plurality of carboxylic groups (—COOH); performing a silylation for adding at least one silane having a hydrophobic group to the hydroxyl groups and the carboxylic groups, so as to form a first hydrophobic light-scattering material; providing a transparent insulating material; and dispersing the first hydrophobic light-scattering material and a wavelength-conversion material into the transparent insulating material.

According to one embodiment of the present disclosure, the core material includes a metal compound, a nonmetal compound, and a metal compound and a nonmetal compound.

According to one embodiment of the present disclosure, the metal compound includes titanium oxide, aluminum oxide, aluminum nitride, zinc oxide or zirconium oxide.

According to one embodiment of the present disclosure, the nonmetal compound includes silicon oxide, boron nitride or a clay.

According to one embodiment of the present disclosure, the silane having the hydrophobic group includes trimethoxy(octadecyl) silane, 1H,1H,2H,2H-perfluorotriethoxysilane or trichloro(1H,1H,2H,2H-perfluorooctyl) silane.

According to one embodiment of the present disclosure, the molar ratio of the silane having the hydrophobic group and the core material is 3:1.

According to one embodiment of the present disclosure, in performing the silylation, the method further includes the steps of: performing an addition of a four-hydroxyl silane to the hydroxyl groups and the carboxylic groups to form an intermediate; and performing a reaction of the intermediate and an alcohol having a hydrophobic group to form a second hydrophobic light-scattering material.

According to one embodiment of the present disclosure, the alcohol having a hydrophobic group includes an octadecyl alcohol or 1H, 1H,2H,2H-perfluorooctyl alcohol.

According to one embodiment of the present disclosure, the transparent insulating material includes a transparent silicone or a transparent plastic.

According to one embodiment of the present disclosure, the wavelength-conversion material includes a fluorescent powder, a dye, a pigment or a combination thereof.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 is a schematic view of packing material according to one embodiment of the present disclosure;

FIGS. 2A-2B are schematic views at various stages of manufacturing a hydrophobic light-scattering material according to one embodiment of the present disclosure;

FIGS. 3A-3B are schematic views at various stages of manufacturing a hydrophobic light-scattering material according to one embodiment of the present disclosure; and

FIG. 4 is a schematic view of LED packing structures according to one embodiment of the present disclosure.

### DETAILED DESCRIPTION

The embodiments of the transparent heat-conducting structure and a method for manufacturing the same of the present disclosure are discussed in detail below, but not limited the scope of the present disclosure. The same symbols or numbers are used to the same or similar portion in the drawings or the description. And the applications of the present disclosure are not limited by the following embodiments and examples which the person in the art can apply in the related field.

The singular forms “a,” “an” and “the” used herein include plural referents unless the context clearly dictates otherwise. Therefore, reference to, for example, a metal layer includes embodiments having two or more such metal layers, unless the context clearly indicates otherwise. Reference throughout this specification to “one embodiment” means that a particular feature, structure, or characteristic described in connection with the embodiment is included in at least one embodiment of the present disclosure. Therefore, the appearances of the phrases “in one embodiment” or “in an embodiment” in various places throughout this specification are not necessarily all referring to the same embodiment. Further, the particular features, structures, or characteristics may be combined in any suitable manner in one or more embodiments. It should be appreciated that the following figures are not drawn to scale; rather, the figures are intended; rather, these figures are intended for illustration.

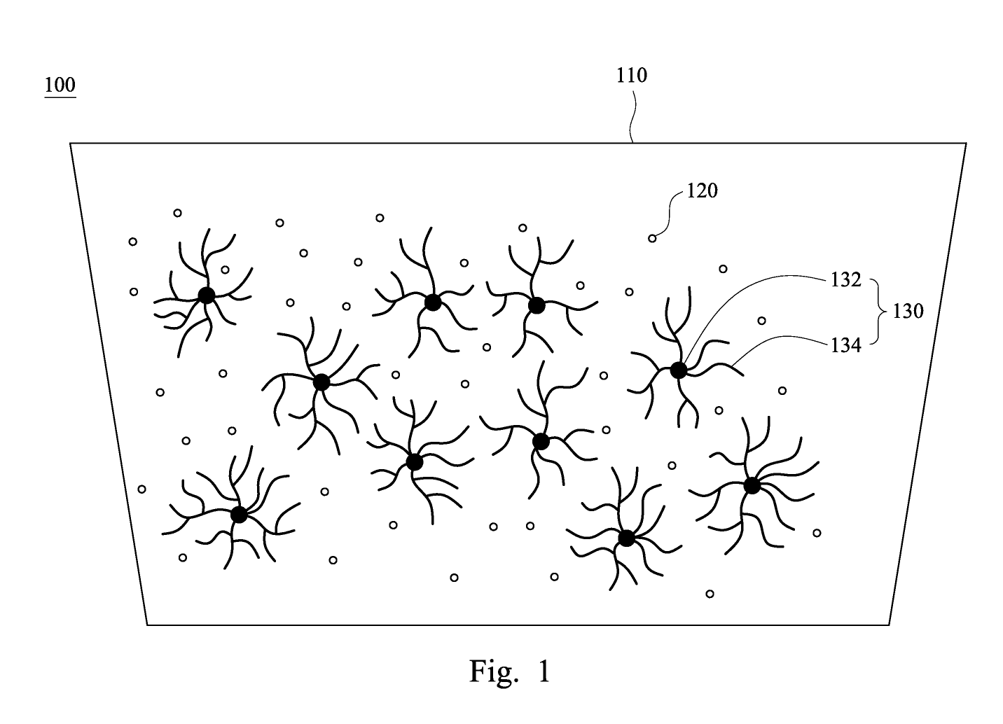

FIG. 1 is a schematic view of packing material 100 according to one embodiment of the present disclosure. In FIG. 1, the packaging material 100 includes a transparent insulating material 110, a wavelength-conversion material 120 and a hydrophobic light-scattering material 130.

The wavelength-conversion material 120 and the hydrophobic light-scattering material 130 are dispersed in the transparent insulating material 110, and the transparent insulating material 110 includes a transparent silicone or a transparent plastic. According to one embodiment of the present disclosure, the wavelength-conversion material 120 and the hydrophobic light-scattering material 130 are in graininess. According to one embodiment of the present disclosure, the content of the wavelength-conversion material 120 in the packaging material 100 is in a range of 0.1-1 wt %. According to one embodiment of the present disclosure, the wavelength-conversion material 120 is a fluorescent powder, a dye, a pigment or a combination thereof.

The hydrophobic light-scattering material 130 includes a core material 132 and a hydrophobic structure positioned 134 on a surface of the core material 132. According to one embodiment of the present disclosure, the core material 132 includes a metal compound and/or a nonmetal compound. In an embodiment, the metal compound includes titanium oxide, aluminum oxide, aluminum nitride, zinc oxide or zirconium oxide. In an embodiment, the nonmetal compound includes silicon oxide, boron nitride or a clay.

According to one embodiment of the present disclosure, the hydrophobic structure 134 is composed of a plurality of hydrophobic side chains. In an embodiment, the hydrophobic side chains include trimethoxy(octadecyl) silane, 1H,1H,2H,2H-perfluorotriethoxysilane or trichloro(1H,1H,2H,2H-perfluorooctyl) silane. According to one embodiment of the present disclosure, the molar ratio of the hydrophobic side chains and the core material is 3:1.

The hydrophobic light-scattering material 130 has the hydrophobic structure 134, and the hydrophobic structure 134 is composed of a plurality of hydrophobic silanes, so that the hydrophobic silanes have the best matching to the transparent silicone as the transparent insulating material 110 to homogeneously disperse the hydrophobic light-scattering material 130 into the transparent insulating material 110. Further, the hydrophobic structure 134 of the hydrophobic light-scattering material 130 may enhance the hydrophilicity of the packaging material 100, so as to prevent water vapor and sulfur vapor enter into a packaging structure and increase the reliability of the packaging material 100.

In addition, the hydrophobic light-scattering material 130 is in graininess, and has a good light-scattering property, so that the content of wavelength-conversion material 120 may be reduced while the addition of the hydrophobic light-scattering material 130 in the packaging material 100 which has the same brightness. Because of reducing the content of wavelength-conversion material 120, the wavelength-conversion material 120 may be well dispersed in the transparent insulating material 110.

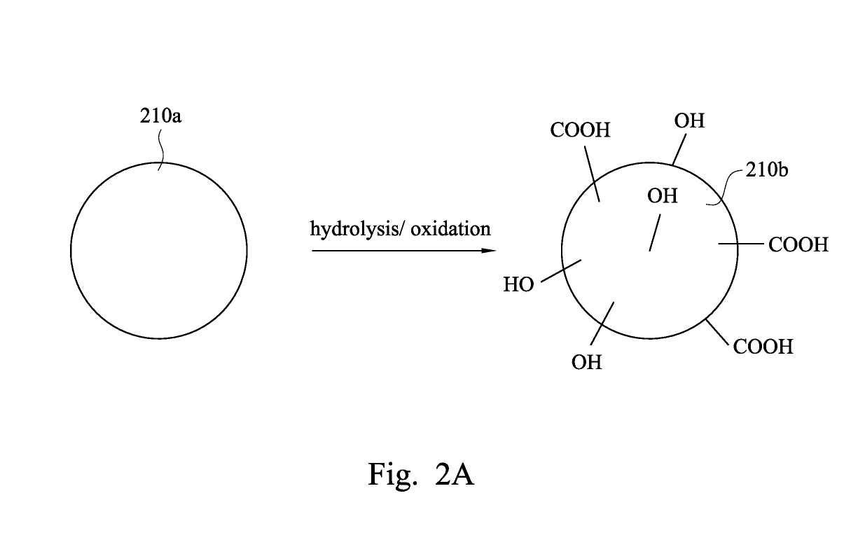

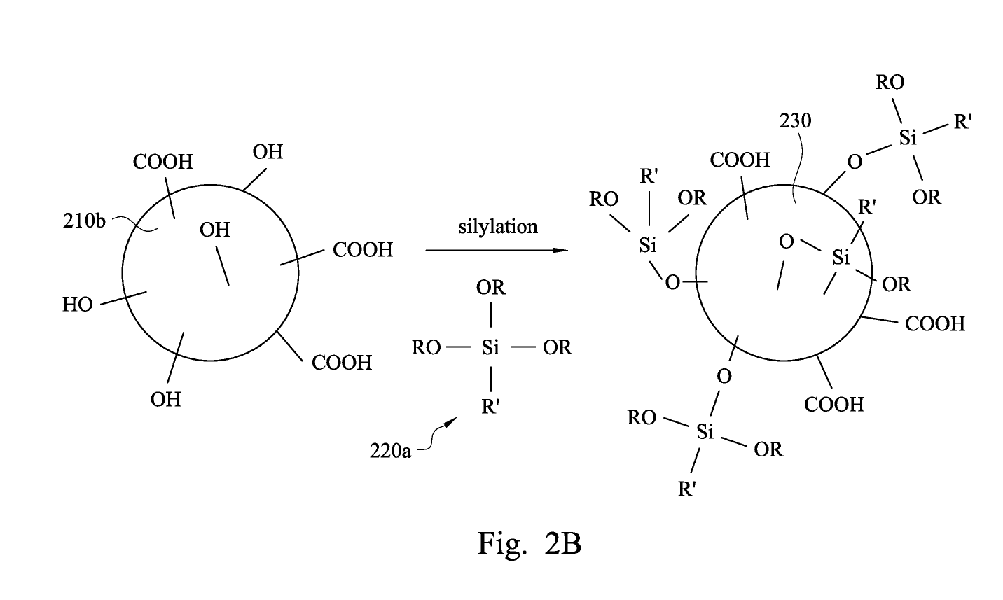

FIGS. 2A-2B are schematic views at various stages of manufacturing a hydrophobic light-scattering material 230 according to one embodiment of the present disclosure. In FIG. 2A, a core material 210a is provided. In an embodiment, the core material 210a includes a metal compound and/or a nonmetal compound. In an embodiment of the present disclosure, the metal compound includes titanium oxide, aluminum oxide, aluminum nitride, zinc oxide or zirconium oxide. In an embodiment of the present disclosure, the nonmetal compound includes silicon oxide, boron nitride or a clay. A hydration of the core material 210a is performed to form a plurality of hydroxyl groups (—OH) on a surface of the core material 210a. Then, a part of the hydroxyl groups is oxidized to form a plurality of carboxylic groups (—COOH). The hydroxyl groups and the carboxylic groups are formed on a surface of the core material 210a by the hydration and the oxidization of the core material 210a.

In FIG. 2B, a silylation is performed. At least one silane 220a having a hydrophobic group is added onto the hydroxyl groups and the carboxylic groups, so as to form a hydrophobic light-scattering material 230. According to one embodiment of the present disclosure, the silane having the hydrophobic group includes trimethoxy(octadecyl) silane, 1H,1H,2H,2H-perfluorotriethoxysilane or trichloro(1H,1H,2H,2H-perfluorooctyl) silane. The surface of the core material 210b has hydroxyl groups and carboxylic groups which may be performed a hydrosilylation with the silane 220a having a hydrophobic group, such that the silane 220a having a hydrophobic group may be added onto the hydroxyl groups and the carboxylic groups of core material 210b to provide a hydrophobic light-scattering material 230. According to one embodiment of the present disclosure, the molar ratio of the silane having the hydrophobic group and the core material is 3:1.

Furthermore, a transparent insulating material is provided, and the hydrophobic light-scattering material 230 and a wavelength-conversion material are dispersed into the transparent insulating material, so as to provide a packaging material which may be applied in LEDs. In this embodiment, the transparent insulating material includes a transparent silicone or a transparent plastic. According to one embodiment of the present disclosure, the wavelength-conversion material is a fluorescent powder, a dye, a pigment or a combination thereof.

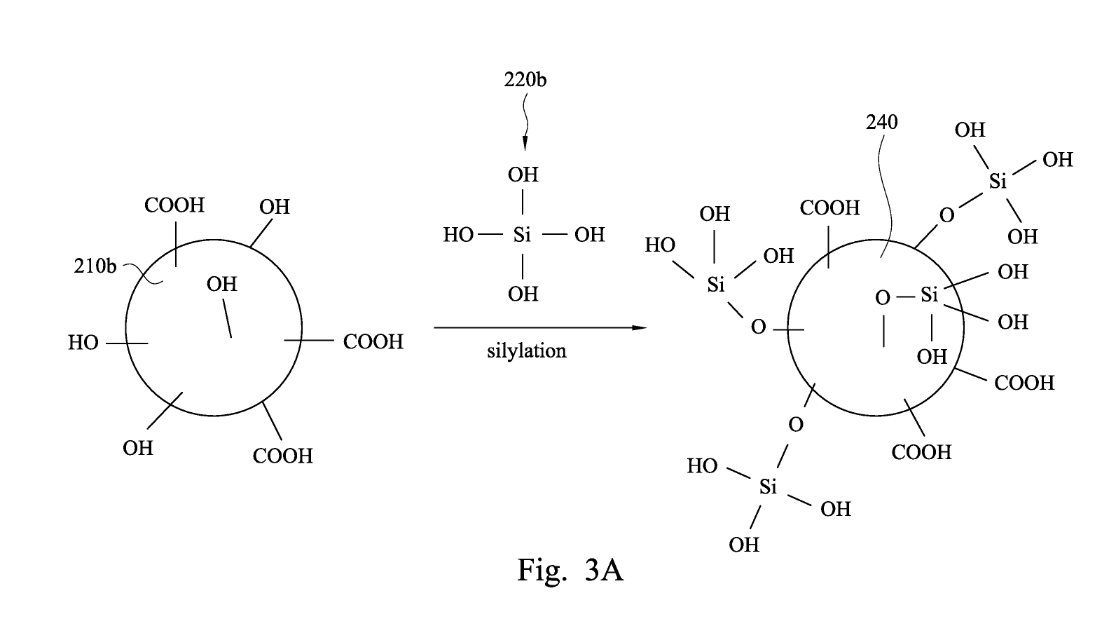

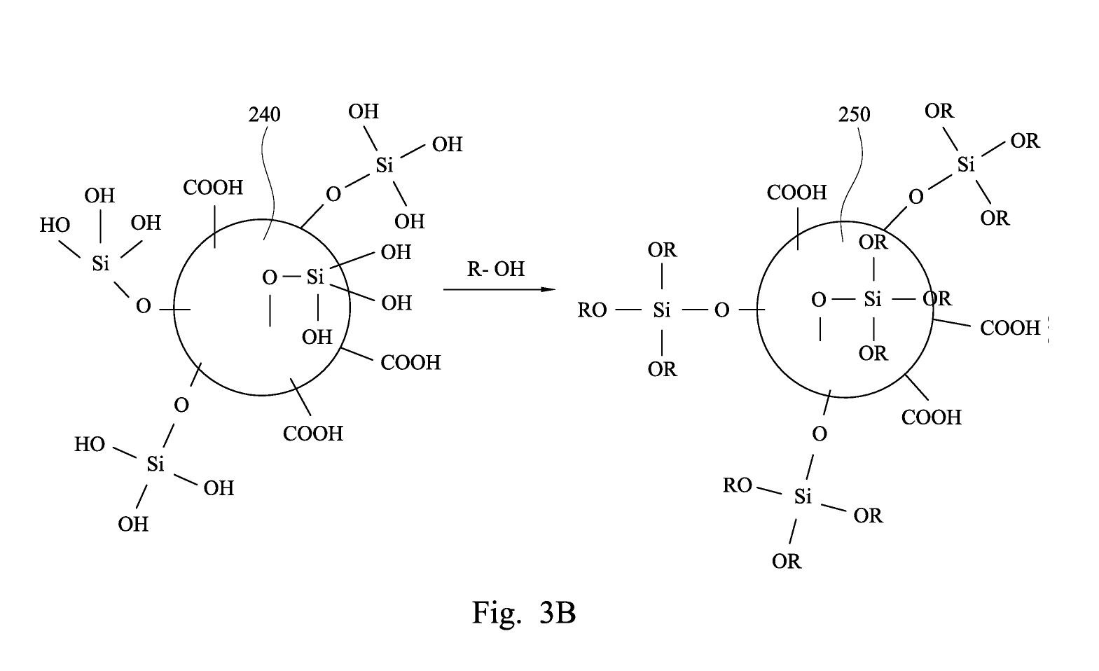

Besides the method for manufacturing the hydrophobic light-scattering material 230 in FIGS. 2A-2B, FIGS. 3A-3B are schematic views at various stages of manufacturing a hydrophobic light-scattering material 250 according to one embodiment of the present disclosure. Followed by FIG. 2A. FIG. 3A shows that the core material 210b and a four-hydroxyl silane 220b are performed a silylation to add the four-hydroxyl silane 220b to the hydroxyl groups and the carboxylic groups on a surface of the core material 210b, so as to form an intermediate 240.

Then, in FIG. 3B, a reaction of the intermediate 240 and an alcohol having a hydrophobic group is performed to form a hydrophobic light-scattering material 250. The surface of the intermediate 240 has carboxylic groups and hydroxyl silyl groups which may be performed an addition with an alcohol having hydrophobic groups, such that the hydrophobic light-scattering material 250 may be formed. According to one embodiment of the present disclosure, the alcohol having a hydrophobic group includes an octadecyl alcohol or 1H,1H,2H,2H-perfluorooctyl alcohol.

Furthermore, a transparent insulating material is provided, and the hydrophobic light-scattering material 250 and a wavelength-conversion material are dispersed into the transparent insulating material, so as to provide a packaging material which may be applied in LEDs. In this embodiment, the transparent insulating material includes a transparent silicone or a transparent plastic. According to one embodiment of the present disclosure, the wavelength-conversion material is a fluorescent powder, a dye, a pigment or a combination thereof.

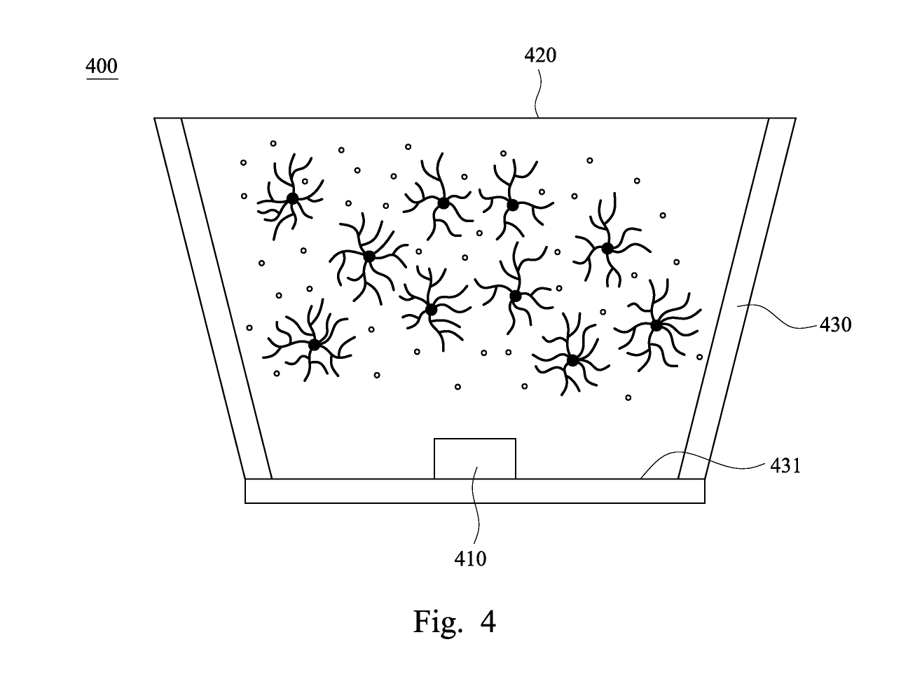

FIG. 4 is a schematic view of an LED packing structure 400 according to one embodiment of the present disclosure. In FIG. 4, the LED packaging structure 400 includes at least one LED chip 410 and the packaging material 420.

In this embodiment, the packaging material 420 covers the LED chip 410. The packaging material 420 includes a transparent insulating material, a wavelength-conversion material and a hydrophobic light-scattering material.

The wavelength-conversion material and the hydrophobic light-scattering material are in graininess. When the LED chip 410 emits an exciting light with a short wavelength, the exciting light is absorbed by the wavelength-conversion material, and then a light with a longer wavelength is emitted. By the time, the hydrophobic light-scattering material has a good light-scattering property, so that the content of wavelength-conversion material may be reduced while the addition of the hydrophobic light-scattering material in the packaging material 420 which has the same brightness. Because of reducing the content of wavelength-conversion material, the wavelength-conversion material may be well dispersed in the transparent insulating material.

In addition, the hydrophobic light-scattering material has the hydrophobic structure, and the hydrophobic structure is composed of a plurality of hydrophobic silanes, so that the hydrophobic silanes have the best matching to the transparent silicone as the transparent insulating material to homogeneously disperse the hydrophobic light-scattering material into the transparent insulating material. Further, the hydrophobic structure of the hydrophobic light-scattering material may enhance the hydrophilicity of the packaging material 420, so as to prevent water vapor and sulfur vapor enter into a packaging structure and increase the reliability of the packaging material 420.

In FIG. 4, the packaging structure 400 further includes a plastic cup 430. The plastic cup 430 has a chip mounting area 431. The LED chip 410 is positioned on the chip mounting area 431, and the packaging material 420 is filled in the plastic cup 430, and covers the LED chip 410.

In the present disclosure, FIG. 4 is a PLCC (plastic leaded chip carrier) packaging type including a plastic cup, but do not limit the present disclosure. In other embodiments, the present disclosure may be applied in various packaging type including wavelength-conversion materials and transparent insulating material, such as COB (chip on board) or an emitter.

Although embodiments of the present disclosure and their advantages have been described in detail, they are not used to limit the present disclosure. It should be understood that various changes, substitutions and alterations can be made herein without departing from the spirit and scope of the present disclosure. Therefore, the protecting scope of the present disclosure should be defined as the following claims.

What is claimed is:

1. A packaging material, comprising:
a transparent insulating material;
a wavelength-conversion material dispersed in the transparent insulating material; and
a hydrophobic light-scattering material dispersed in the transparent insulating material.

2. The packaging material of claim 1, wherein the transparent insulating material comprises a transparent silicone or a transparent plastic.

3. The packaging material of claim 2, wherein the wavelength-conversion material and the hydrophobic light-scattering material are in shape of graininess.

4. The packaging material of claim 3, wherein the content of the wavelength-conversion material in the packaging material is in a range of 0.1-1 wt %.

5. The packaging material of claim 3, wherein the wavelength-conversion material comprises a fluorescent powder, a dye, a pigment or a combination thereof.

6. The packaging material of claim 1, wherein the hydrophobic light-scattering material comprises a core material and a hydrophobic structure positioned on a surface of the core material.

7. The packaging material of claim 6, wherein the core material comprises a metal compound, a nonmetal compound, or a metal compound and a nonmetal compound.

8. The packaging material of claim 7, wherein the metal compound comprises titanium oxide, aluminum oxide, aluminum nitride, zinc oxide or zirconium oxide.

9. The packaging material of claim 7, wherein the nonmetal compound comprises silicon oxide, boron nitride or a clay.

10. The packaging material of claim 6, wherein the hydrophobic structure is composed of a plurality of hydrophobic side chains.

11. The packaging material of claim 10, wherein the hydrophobic side chains includes trimethoxy(octadecyl) silane, 1H,1H,2H,2H-perfluorotriethoxysilane or trichloro(1H,1H,2H,2H-perfluorooctyl) silane.

12. The packaging material of claim 10, wherein the molar ratio of the hydrophobic side chains and the core material is 3:1.

13. An LED packaging structure, comprising:
at least one LED chip; and
a packaging material of claim 1 covering the LED chip.

14. A method for manufacturing a packaging material, comprising:
providing a core material;
performing a hydration of the core material to form a plurality of hydroxyl groups (—OH) on a surface of the core material;
oxidizing a part of the hydroxyl groups to form a plurality of carboxylic acid groups (—COOH);
performing a silylation for adding at least one silane having a hydrophobic group to the hydroxyl groups and the carboxylic groups, so as to form a first hydrophobic light-scattering material;
providing a transparent insulating material; and
dispersing the first hydrophobic light-scattering material and a wavelength-conversion material into the transparent insulating material.

15. The method of claim 14, wherein the core material comprises a metal compound, a nonmetal compound, or a metal compound and a nonmetal compound.

16. The method of claim 15, wherein the metal compound comprises titanium oxide, aluminum oxide, aluminum nitride, zinc oxide or zirconium oxide.

17. The method of claim 15, wherein the nonmetal compound comprises silicon oxide, boron nitride or a clay.

18. The method of claim 14, wherein the silane having the hydrophobic group includes trimethoxy(octadecyl) silane, 1H,1H,2H,2H-perfluorotriethoxysilane or trichloro(1H,1H,2H,2H-perfluorooctyl) silane.

19. The method of claim 14, wherein the molar ratio of the silane having the hydrophobic group and the core material is 3:1.

20. The method of claim 14, in performing the silylation, further comprising:
performing an addition of a four-hydroxyl silane to the hydroxyl groups and the carboxylic groups to form an intermediate; and
performing a reaction of the intermediate and an alcohol having a hydrophobic group to form a second hydrophobic light-scattering material.

21. The method of claim 20, wherein the alcohol having a hydrophobic group comprises an octadecyl alcohol or 1H,1H,2H,2H-perfluorooctyl alcohol.

22. The method of claim 14, wherein the transparent insulating material comprises a transparent silicone or a transparent plastic.

23. The method of claim 14, wherein the wavelength-conversion material comprises a fluorescent powder, a dye, a pigment or a combination thereof.
